(19) United States
(12) Patent Application Publication
(10) Pub. No.: US 2026/0209991 A1
(43) Pub. Date: Jul. 23, 2026

(54) COMPOSITE STRUCTURE COMPRISING A MONOCRYSTALLINE THIN FILM ON A POLYCRYSTALLINE SILICON CARBIDE SUPPORT SUBSTRATE, AND ASSOCIATED PRODUCTION METHOD

(71) Applicant: Soitec, BERNIN (FR)

(72) Inventors: Hugo Biard, BERNIN (FR); Alexandre Potier, Verneuil Sur Seine (FR); Marc Ferrato, Horgues (FR); Christophe Bommier, Basking Ridge, NJ (US)

(21) Appl. No.: 19/157,785

(22) PCT Filed: Feb. 19, 2024
(86) PCT No.: PCT/EP2024/054102

§ 371 Date: Aug. 19, 2025

(30) Foreign Application Priority Data
Feb. 24, 2023 (FR) FR2301697

(51) Int. Cl. C30B 29/68; C30B 29/04; C30B 29/16; C30B 29/36; C30B 29/40; H10P 90/00

(52) U.S. Cl. CPC C30B 29/68; C30B 29/04; C30B 29/16; C30B 29/36; C30B 29/406; H10P 90/1916

(57) ABSTRACT

A composite structure for manufacturing microelectronic components, includes a monocrystalline thin film on a support substrate made of polycrystalline silicon carbide, the support substrate having, on each of its faces, a preferential crystalline orientation on each of its faces, according to which: a texture coefficient C₄₂₂ is less than 40%, and the sum of texture coefficients C₂₂₀+C₂₀₀+C₄₀₀ is greater than 50%, preferably greater than 80%. A method is used to manufacture such a composite structure.

### CROSS-REFERENCE TO RELATED APPLICATIONS

This application is a national phase entry under 35 U.S.C. § 371 of International Patent Application PCT/EP 2024/054102, filed Feb. 19, 2024, designating the United States of America and published as International Patent Publication WO 2024/175519 A1 on Aug. 29, 2024, which claims the benefit under Article 8 of the Patent Cooperation Treaty of French Patent Application Serial No. FR2301697, filed Feb. 24, 2023.

### TECHNICAL FIELD

The present disclosure relates to the field of semiconductor materials for microelectronic components. It relates, in particular, to a composite structure comprising a monocrystalline thin film arranged on a support substrate made of polycrystalline silicon carbide. The monocrystalline thin film is preferably made of silicon carbide, and the composite structure is intended for power electronics applications.

### BACKGROUND

SiC is increasingly widely used in the manufacture of innovative power devices, to meet the needs of rising fields of electronics, such as, in particular, electric vehicles. Indeed, the power devices and integrated power supply systems based on monocrystalline silicon carbide can manage a much higher power density compared to their traditional silicon counterparts, and do so with lower active area dimensions.

High-quality monocrystalline SiC substrates (c-SiC), intended for the microelectronics industry, remain expensive and difficult to supply in large size. It is therefore advantageous to resort to solutions for transferring layers, to produce composite structures typically comprising a thin film made of monocrystalline SiC (from the high-quality c-SiC substrate) on a lower-cost support substrate, for example, made of polycrystalline SiC (p-SiC). The electronic components can then be produced on and/or in the thin film.

A well-known thin-layer transfer solution is the Smart Cut™ method, based on light-ion implantation and direct bonding between a donor monocrystalline substrate and a support substrate, at a bonding interface.

P-SiC substrates capable of forming support substrates are currently available on the market. However, their mechanical, electrical, or even thermal characteristics are not necessarily optimal for obtaining a high-quality composite structure intended for power applications using a thin film transfer method.

As mentioned above, power electronics applications require excellent vertical electrical conduction in the composite structure. The monocrystalline thin film can thus be doped, depending on the requirements of the application: for example, to exhibit n-or p-doping and a resistivity of less than 30 mOhm·cm, at 10 mOhm·cm, or even less than 1 mOhm·cm. The assembly interface of the composite structure must be produced so as to not (or very slightly) increase the vertical electrical resistance. Finally, good electrical conductivity must be ensured in the support substrate of the composite structure. It is therefore required to strongly dope (n- or p-doping) the polycrystalline substrate to achieve a resistivity of less than or equal to 15 mOhm·cm, 10 mOhm·cm, or even less than 5 mOhm·cm. However, it is known that a high concentration of doping agents, for example, nitrogen, in a p-SiC material may be a limiting factor in obtaining good flatness (low deformation) due to a large density of defects generated.

However, it is essential to use support substrates having a low curvature or deformation. The curvature corresponds to the flexion or “warp,” which is equivalent to the algebraic difference of the deviations of the substrate relative to a reference plane. A reduced curvature is required on the one hand, so that these support substrates are compatible with direct assembly of good quality and a high bonding energy, and on the other hand, so that they are not likely to cause damage to the monocrystalline thin film during or after the transfer process, due to significant mechanical stresses. A small curvature is also important to guarantee the performance of the manufacturing steps (for example, photolithography) of the components on/in the thin film of the composite structure. The radius of curvature (proportional to the inverse of the warp) of the support substrates made of p-SiC is typically targeted to be greater than about 25 m (either a warp less than 100 μm for a substrate with a diameter of 150 mm, or even less than 50 μm, or ideally less than 30 μm).

Finally, a thin film transfer method, based on direct bonding by molecular adhesion, is very dependent on the surface quality of the assembled substrates. In particular, a roughness of less than or equal to 1 nm RMS (root mean square roughness) is required, combined with surface defects (particles, holes, etc., or other reliefs capable of generating bonding defects), both for the support substrate and for the donor substrate. It should be noted that the hardness of SiC and the presence of grains on the surface of the polycrystalline support substrate greatly complicates the surface preparation, and perfect quality has proven to be difficult to obtain.

In addition, it often appears important that the support substrate guarantees good thermal conductivity (typically greater than 200 W/(m·K), or even greater than 250 W/(m·K)), to effectively discharge heat, in particular, heat generated by power components. However, thermal conductivity may be unfavorably impacted by a high degree of doping agent, which is detrimental to the propagation of phonons, in particular, due to the generation of additional crystalline defects.

All of these specifications are very complex to achieve with currently available p-SiC substrates.

U.S. Pat. No. 10,934,634 proposes a p-SiC substrate for which the rate of change of the size of the grains between the two faces of the substrate is less than 0.43%, which provides the substrate with a radius of curvature greater than 142 m, i.e., a very low deformation. Furthermore, a face at least of the substrate has an arithmetic average roughness of less than 1 nm. This method, however, remains expensive and consumes a lot of energy and material, since a large portion of the p-SiC initially deposited on a graphite substrate is removed and lost to obtain the proposed substrate made of p-SiC (typically 2 mm initially deposited to form a p-SiC substrate of 350 μm).

To reduce manufacturing costs, it would be optimal to grow, by high-speed chemical vapor deposition, a layer of p-SiC with a thickness as close as possible to the final thickness of the desired substrate, with a very rapidly stabilized grain size after the start of the growth of the layer, to avoid any unnecessary thickness, which would become necessary to reduce or eliminate the gradient of grain size that is harmful to the flatness of the substrate. This is done by ensuring a very high concentration of doping agents (for example, of type n, such as nitrogen or phosphorus), typically greater than 5×10¹⁹atoms/cm³ , preferably greater than 10²⁰ atoms/cm³, to typically achieve a resistivity of the material less than 15 mOhm·cm, or even less than 10 mOhm·cm, and allowing good thermal conductivity.

### BRIEF SUMMARY

The present disclosure proposes a composite structure comprising a thin film made of monocrystalline material, in particular, of c-SiC, of high quality, arranged on a p-SiC support substrate having very low resistivity, low deformation and good thermal conductivity. It also relates to a method for manufacturing such a composite structure.

The present disclosure relates to a composite structure for the manufacture of microelectronic components comprising a monocrystalline thin film, arranged on a support substrate made of polycrystalline silicon carbide, the support substrate having, on each of its faces, a preferential crystalline orientation according to which:
a texture coefficient C₄₂₂ is less than 40%, and
the sum of texture coefficients C₂₂₀+C₂₀₀+C₄₀₀ is greater than 50%, preferably greater than 80%.

According to other advantageous and non-limiting features of the present disclosure, either individually or in any technically feasible combination:
the support substrate has an electrical resistivity less than or equal to 10 mOhm·cm, preferably less than or equal to 5 mOhm·cm, more preferably less than or equal to 3 mOhm·cm;
the support substrate is nitrogen-doped with a concentration, measured by secondary ion mass spectroscopy, of greater than or equal to 5.0×10¹⁹ atoms/cm³, preferably greater than or equal to 1.0×10²⁰ atoms/cm³, even more preferably greater than or equal to 1.5×10²⁰ atoms/cm³, or preferably greater than or equal to 3×10²⁰ atoms/cm³;
the texture coefficients C₄₂₂ is less than 20%, preferably less than 15%, or even preferably less than 10%;
the sum of the texture coefficients C₂₀₀+C₄₀₀ is greater than 1%, preferably greater than 2%, even more preferably greater than 5%;
the thin film is composed of silicon carbide;
the thin film is composed of gallium nitride;
the thin film is composed of gallium oxide;
the thin film is composed of diamond;
the composite structure comprises a continuous or discontinuous intermediate layer, arranged between the thin film and the support substrate and composed of at least one metallic or semi-conductive material;
the intermediate layer is composed of silicon, silicon carbide, tungsten, and/or titanium;
the support substrate has a thickness between 50 micrometers and 650 micrometers;
the composite structure comprises an electronic component on and/or in the thin film and optionally comprising an electrical contact at the rear face of the support substrate.

The present disclosure also relates to a method for manufacturing a composite structure comprising a monocrystalline thin film arranged on a support substrate made of polycrystalline silicon carbide, the manufacturing method comprising the following steps:
a) providing a polycrystalline silicon carbide support substrate having, on each of its faces, a preferential crystalline orientation according to which:
   a texture coefficient C₄₂₂ is less than 40%, and
   the sum of texture coefficients C₂₂₀+C₂₀₀+C₄₀₀ is greater than 50%, preferably greater than 80%.
b) providing a donor substrate made of a monocrystalline material,
c) transferring a thin film from the donor substrate onto the support substrate.

According to other advantageous and non-limiting features of the present disclosure, either individually or in any technically feasible combination:
the step c) of transferring comprises:
   c1) forming a buried brittle plane in the donor substrate, delimiting the thin film between the buried brittle plane and a front face of the donor substrate,
   c2) assembling, by molecular adhesion bonding, the donor substrate to the support substrate, directly or via an intermediate layer,
   c3) separating along the buried brittle plane to result in transfer of the thin film onto the support substrate;
step c2) comprises, before the assembly of the two substrates:
   forming an intermediate layer on the donor substrate, before or after step c1), and/or
   forming an intermediate layer on the support substrate, the intermediate layer being formed of at least one metallic or semi-conductive material, chosen from silicon, silicon carbide, tungsten and titanium;
the manufacturing method further comprises the production of electronic components on and/or in the thin film of the composite structure;
the creation of electronic components comprises, in particular, a step of homoepitaxy or heteroepitaxy on the thin film.

### BRIEF DESCRIPTION OF THE DRAWINGS

Other features and advantages of the present disclosure will emerge from the following detailed description of the present disclosure with reference to the appended figures, in which:

FIG. 1 shows a composite substrate according to the present disclosure;

FIG. 2 shows a table listing the 10 diffraction peaks, classified by increasing Miller (hkl) indices, taken into account in a 3C-polytype SiC substrate and measurable by X-ray diffraction; also indicated in the table are the positions of the peaks and their theoretical intensity;

FIGS. 3A and 3B show images obtained by scanning electron microscopy of backscattered electrons of a cross-section, respectively of a raw disc made of p-SiC and of a support substrate from the raw disc, the support substrate being implemented to manufacture composite structures according to the present disclosure;

FIG. 4 shows a composite substrate according to the present disclosure;

FIGS. 5A, 5B, 5C, 5C′, 5C″, and 5D show steps of the manufacturing method according to the present disclosure.

The same references in the figures may be used for elements of the same type. Some figures are schematic depictions, which, for the sake of readability, are not to scale. In particular, the thicknesses of the layers along the z axis are not to scale with respect to the lateral dimensions along the x and y axes; and the relative thicknesses of the layers between them are not necessarily respected in the figures.

### DETAILED DESCRIPTION

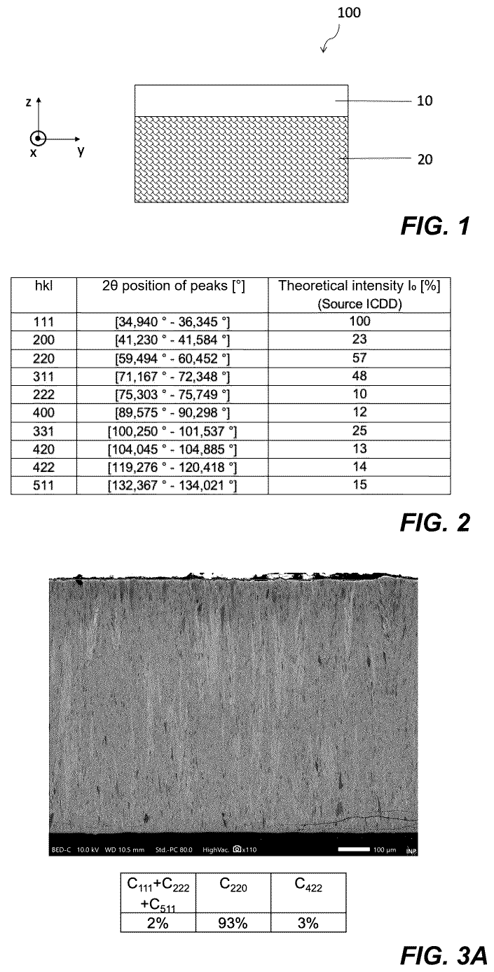

The present disclosure relates to a composite structure 100 particularly suitable for manufacturing microelectronic components comprising a monocrystalline thin film 10, in particular, made of silicon carbide, diamond, silicon, II-VI or III-V semiconductor compounds (for example, AlN, GaN, etc.), gallium oxide (Ga₂O₃), or any wide-bandgap semiconductor material, arranged on a support substrate 20 made of polycrystalline silicon carbide (FIG. 1).

In a main plane (x, y), the composite structure 100 is preferably in the form of a circular wafer with a diameter of 100 mm, 150 mm, 200 mm, or even more. However, it could be in any other form that allows it to be processed later for the manufacture of components. The thickness of the composite structure 100 extends along the z axis in the Figures.

The thin film 10 of the composite structure 100 has a thickness typically between a few tens of nm and a few hundred nm, for example, between 50 nm and 800 nm. It will be seen below that epitaxy steps can be implemented on the thin film 10 so as to thicken it (homoepitaxy) or to grow other materials (heteroepitaxy) for the needs of the electronic components to be manufactured.

The thin film 10 has an electrical resistivity adapted to the present disclosure and to the intended components. For example, for power components, its resistivity is usually less than 30 mOhm·cm, 10 mOhm·cm, or even 1 mOhms·cm, with n-doping (nitrogen or phosphorus doping agent).

The support substrate 20 corresponds to the mechanical support of the composite structure 100. The lateral dimensions in the main plane (x, y) of the support substrate 20 (its diameter, in particular) are the same as those of the composite structure 100. It should be noted that the thin film 10 may have a slightly lower lateral dimension, due to the transfer method: indeed, a peripheral ring of the support substrate 20 is usually free of a thin film 10 because the edge dropping or the chamfer of the substrate 20 prevent the assembly and the effective transfer of the thin film 10.

In the composite structure 100, the support substrate 20 has a thickness typically between about 50 μm and several hundred micrometers, for example, between 50 μm and 650 μm, or between 100 μm and 450 μm, or between 200 μm and 350 μm. Usually, the thickness of a support substrate 20 with a diameter of 150 mm is in the range of 350-450 μm, and the thickness of a support substrate 20 with a diameter of 200 mm is in the range of 500-650μm.

As mentioned in the introduction, good vertical electrical conductivity is required for power applications. Thus, the support substrate 20 has an electrical resistivity less than or equal to 10 mOhm·cm, preferably less than or equal to 5 mOhm·cm, or even more preferably less than or equal to 3 mOhm·cm. When the thin film 10 is n-type, the type of doping of the support substrate 20 is usually chosen to be identical, i.e., typical doping with nitrogen or phosphorus. To obtain the low resistivity stated above, the dopant concentration (which can be measured by secondary ion mass spectroscopy) is generally greater than 5.0×10¹⁹ atoms/cm³ preferably greater than or equal to 1.0×10²⁰ atoms/cm³, greater than or equal to 1.5×10²⁰ atoms/cm³ or even greater than or equal to 3×10²⁰ atoms/cm³.

The radius of curvature of the support substrate 20 is greater than 25 m, advantageously greater than or equal to 50 m. By way of example, a support substrate 20 whose diameter is 150 mm has a curvature (or warp) of less than or equal to 100 μm, less than or equal to 50 μm, or even less than or equal to 30 μm; a support substrate 20 whose diameter is 200 mm has a curvature (or warp) of less than or equal to 150 μm, less than or equal to 100 μm, less than or equal to 70 μm, or even less than or equal to 40 μm.

The range of radius of curvature of the support substrate 20 makes the support substrate 20 compatible with the specifications of a composite structure 100 provided with a monocrystalline thin film 10, with the method for manufacturing such a composite structure 100 and with the subsequent preparation of microelectronic components on and/or in the thin film 10. Note that the curvature of the composite structure 100 remains close to the curvature of the support substrate 20.

The support substrate 20, made of p-SiC of polytype 3C, furthermore has, on each of its faces, in particular, on each of its two main faces (which are the faces between which the thickness of the support substrate 20 is measured), a preferential crystalline orientation. This crystalline orientation is particularly favorable to obtaining a low curvature, and a good thermal conductivity, in parallel with a high concentration of doping agents.

The preferred crystalline orientation is characterized here with particular proportions of different texture coefficients. A texture coefficient can be expressed as a percentage and quantifies the mean preferential orientation of the crystallites of the support substrate 20 relative to the normal to the surface of the support substrate 20. It will be recalled that the texture coefficients can be measured by virtue of the method described by G. Harris (“X. Quantitative measurement of preferred orientation in rolled uranium bars,” Philosophical Magazine Series 7, 43:336, 113-123, 1952). In practice, they are measured from the diffraction peaks collected by an X-ray diffractometer of the PANalytical X'Pert PRO MPD type, by the 0 -2θ method over a range of angles from 10° to 135 ° (2θ scale). On this range, the ten diffraction peaks appearing in the table (shown in FIG. 2) and classified according to increasing Miller (hkl) indices, can be taken into account in a 3C type SiC substrate.

A texture coefficient Cₕₖₗ is calculated from the intensity of the peak Iₕₖₗ, proportional to the area under the peak of the sample, and the theoretical intensity I_{0 hkl} of a powder, which can be obtained from the theoretical percentages edited by the ICDD (International Centre for Diffraction Data). A texture coefficient Cₕₖₗ is expressed as follows:
Cₕₖₗ=(Iₕₖₗ/I_{0 hkl})/(1/N×Σ(Iₕₖₗ/I_{0 hkl})), where N is the number of peaks taken into account.

The preferential crystalline orientation of the support substrate 20 is characterized by a texture coefficient C₄₂₂ of less than 40%, and by the fact that the sum of the texture coefficients C₂₂₀+C₂₀₀+C₄₀₀ is greater than 50%.

Preferably, the sum of texture coefficients C₂₂₀+C₂₀₀+C₄₀₀ is greater than 60%, 70%, or even 80%. Contribution C₂₀₀+C₄₀₀ may advantageously be greater than 1%, 2%, or even 5%.

Also preferably, the texture coefficient C₄₂₂ is less than 20%, less than 15%, or even less than 10%.

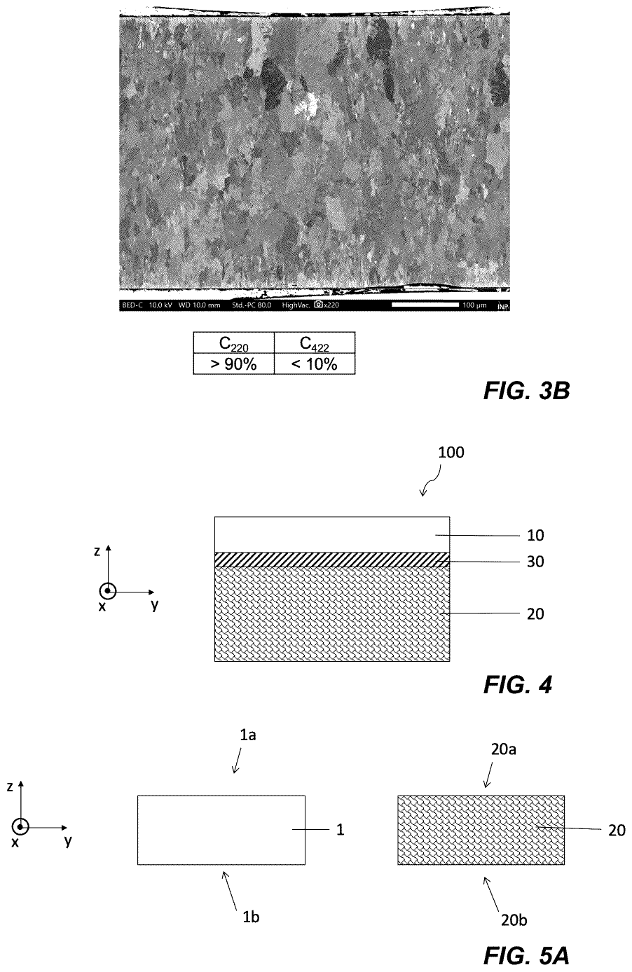

FIG. 3B has an example texture of a support substrate 20 for a composite structure 100 according to the present disclosure. The image was obtained by scanning electron microscopy (SEM) with electron backscatter diffraction (EBSD), in the transverse plane (y, z), i.e., in a cross-section of the support substrate 20; the white bar at the bottom-right of the image indicates a scale of 100 μm. The texture observed is preferably oriented (220) with a texture coefficient C₂₂₀ greater than or equal to 90% and a texture coefficient C₄₂₂ less than 10%.

In this example, the support substrate 20 has a nitrogen concentration of 1.8×10²⁰ atoms/cm 3 and an electrical resistivity of 1.2 mOhm·cm measured by the 4-point method. The thermal conductivity, on the order of 270 W/(m·K) is deduced from a thermal diffusivity measurement by the laser flash method. Finally, the deformation (warp) is measured to be less than 100 μm on a substrate with a diameter of 150 mm and a thickness of between 350 μm and 450 μm.

Preferred textures, associated with high doping, make it possible to obtain a support substrate 20 satisfying the expected physical, mechanical and electrical specifications in the composite structure 100, namely excellent flatness (low curvature), low electrical resistivity and very good thermal conductivity.

According to a particular embodiment of the present disclosure, the composite structure 100 comprises a continuous or discontinuous intermediate layer 30, arranged between the thin film 10 and the support substrate 20 and composed of at least one metallic or semi-conductor material (FIG. 4). As will be described below, with reference to a method for manufacturing the composite structure 100, the intermediate layer 30 may be formed on the side of the thin film 10, on the side of the support substrate 20 or on both sides, prior to the assembly along a bonding interface 40.

The intermediate layer 30 may, for example, be composed of silicon, silicon carbide, tungsten and/or titanium. The thickness of the intermediate layer 30 is typically between a few nm and a few hundred nm, preferably between 2 nm and 50 nm.

The present disclosure also relates to a method for manufacturing the composite structure 100.

The method comprises a first step a) of providing a support substrate 20 made of polycrystalline silicon carbide having a preferential crystalline orientation according to which:
the texture coefficient C₄₂₂ is less than 40%, and
the sum of the texture coefficients C₂₂₀+C₂₀₀+C₄₀₀ is greater than 50%.

Preferably, to address power electronics applications, the support substrate 20 has a nitrogen or phosphorus doping making it possible to achieve an electrical resistivity of less than or equal to 10 mOhm·cm, 5 mOhm·cm, or even less than 3 mOhm·cm.

The radius of curvature of the support substrate 20 is greater than 25 m, advantageously greater than or equal to 50 m.

Step a) implements a chemical vapor deposition (CVD) technique. This technique involves a gas mixture comprising at least one silicon precursor gas (such as a silane or a chlorosilane) and/or at least one carbon precursor gas (such as an alkane or an alkene), and/or at least one silicon and carbon precursor gas (such as methyltrichlorosilane, abbreviated to MTCS), and, if necessary, at least one dopant gas. In the case of nitrogen doping, the dopant gas may, for example, be NH₃, N₂H₄, N₂). It should be noted that the dopant gas may also be a precursor of carbon and/or silicon (for example, an amine such as H₂NCH₃). These gases can be diluted in a carrier gas, which may be a reducing gas such as hydrogen and/or an inert gas such as argon. From this gas mixture, the polycrystalline SiC layer is formed on a so-called growth substrate.

This gas mixture is admitted into a reactor at high temperature where the precursor gases are broken down and react on the surface of the growth substrate, preferably fine and purified grain isostatic graphite, to form the 3C-SiC polytype whose mechanical and thermal resistance properties, thermal expansion coefficient, and purity are perfectly compatible with the specifications of the composite structure 100. The 3C-SiC polytype, moreover, can be doped with nitrogen up to very high levels, typically 10²⁰atoms/cm³, and thus have a resistivity of less than 10 mOhm·cm, without degradation of the substrate quality that would be detrimental to the quality of the composite structure and subsequently to the performance of microelectronic components. Finally, it is a material capable of withstanding high-temperature processes that the support substrate 20 is expected to undergo during the manufacture of the composite structure 100 and components.

The temperature of the reactor during the CVD deposition of the SiC must be between about 1000° C. and about 1600° C., preferably between about 1100° C. and about 1400° C., or even between about 1200° C. and about 1400° C. In this temperature range, the deposition rates can evolve in fairly wide ranges, from one micrometer/h to more than 100 micrometers/h. Advantageously, the total pressure in the reactor does not exceed 350 mbar, or even 300 mbar.

By modifying the parameters of the CVD process such as the temperature, the partial pressure of the precursor and potentially the percentage of dopant gas, it is possible to change the crystalline orientation/the texture of the deposited p-SiC layer.

By way of example, to obtain a support substrate 20 with a diameter of 150 mm, the deposition is carried out on a disc-shaped graphite cylinder, with a diameter approaching a nominal of 150 mm and with a thickness of greater than 2 mm in order to ensure sufficient flatness of the substrate. The reactor may comprise a plurality of these discs, the diameter of which may be identical or different. The two faces of the disks preferably have a flatness <15 μm, obtained by sufficiently precise machining. The thermal expansion coefficient of the isostatic graphite is chosen judiciously to be compatible with the p-SiC layer during cooling after deposition. A substrate marketed by the company MERSEN under the designation “grade 2303” can be used.

At the end of the deposition, the graphite growth substrate, coated with a p-SiC deposition layer, is machined, then air-oxidized typically at 900° C. to remove any graphite residue. It should be noted that the removal of the graphite could also be carried out by mechanical machining techniques alone, or essentially by burning/oxidation. A p-SiC raw disc is recovered for each face of a growth substrate and has a curvature due to the relaxation of the stresses of the deposited layer.

The p-SiC raw disc (optionally, after having been freed, at least on its face, which was in contact with the growth substrate with a material thickness of about 100 μm or more) is provided with particular crystallographic characteristics, namely a preferential crystalline orientation, which is characterized on each of its two faces by:
a texture coefficient C₄₂₂ is less than 40%, preferably less than 30%, and
a texture coefficient C₂₂₀ is greater than 50%, and preferably greater than 60%, or even greater than 80%.

A heat treatment is then applied to the raw disc made of p-SiC, in a temperature range ranging from 1800° C. to 2300° C. During this heat treatment, the raw disc is advantageously held flat on a flat surface. This heat treatment leads to a specific modification of the size of the p-SiC grains and their crystallographic orientation, which is observed only in the case where the raw disc has the aforementioned specific crystallographic characteristics, after deposition. This heat treatment is carried out at a temperature of between 1800° C. and 2300° C., preferably between 1850° C. and 2200° C., more preferably between 1900° C. and 2150° C., and even more preferably between 1950° C. and 2150° C. Its duration is advantageously at least 10 minutes, and is advantageously between about 1 hour and about 12 hours, and preferably between about 2 hours and about 9 hours. Too long a duration may lead to undesired recrystallisation, and at too short a duration, the heat treatment may be ineffective.

The p-SiC raw disc then undergoes thinning by rough rectification, and then fine rectification. These rectification steps, known from the state of the art, in particular, aim to eliminate a sufficient thickness (at least 100 μm) on the side of the face of the disc that was in contact with the graphite, to remove the initial growth zone of the crystals, generating strong stresses. They also make it possible by removing material from both faces of the raw disc to obtain an intermediate p-SiC disc, which has a second thickness close to the final thickness intended for the support substrate 20, and a low deformation. This second thickness is typically less than 550 μm, preferably between 350 μm and 450μm.

It should be noted that the aforementioned steps of thinning by rectification and of heat treatment can be reversed or even nested (the heat treatment may, for example, be carried out after a first rectification sequence applied to the raw disc, and before a second rectification sequence that will result in the intermediate disc).

By virtue of the stated heat treatment, an intermediate disc made of p-SiC is obtained, which has a preferential crystalline orientation, which will also be that of the support substrate 20, defined by:
a texture coefficient C₄₂₂ less than 40%, and
the sum of texture coefficients C₂₂₀+C₂₀₀+C₄₀₀ greater than 50%, preferably greater than 80%.

Preferably, the contribution C₂₀₀+C₄₀₀ is greater than 1%, greater than 2%, or even greater than 5%. It is this contribution C₂₀₀+C₄₀₀ to the crystallographic orientation characterized by a highly dominant texture C₂₂₀, which is generated by the specific heat treatment to which the raw or intermediate disc is subjected.

Advantageously, the intermediate disc has, on each of its two faces, a texture coefficient C₄₂₂, which is less than 20%, preferably less than 15%, and even more preferably less than 10%.

The heat treatment of a raw disc (before or after all or some of the rectification steps) leads first to a rearrangement of crystallographic defects at the grain boundaries (which induces the relaxation of residual stresses at the grain boundaries), then to recrystallisation by nucleation at the grain boundaries, followed by an enlargement of these grains. Thus, the initial grain size can influence the microstructure obtained at the end of the heat treatment. The nature of the crystallographic defects is also critical: to facilitate recrystallisation that effectively relaxes the stresses, the small-sized grains must be bordered with high angle grain boundaries (HAGB). These high-angle grain boundaries contain a particularly large, stored energy, and are consequently more mobile than the low-angle grain boundaries. Their internal energy is the driving force for the rearrangement of defects at the grain boundaries. The particular texture of p-SiC of the raw disc, subjected to the heat treatment, ensures the presence of such high-angle grain boundaries.

Without being bound by this theory, it is also assumed that the heat treatment of the disc made of p-SiC allows better diffusion of the doping agents, in particular, nitrogen, and leads to an electronically more effective incorporation of the doping atoms in the crystallographic network. This makes it possible to obtain a polycrystalline SiC disc, which is doped with a nitrogen concentration of greater than 5×10¹⁹ atoms/cm³, preferably greater than 1×10²⁰ atoms/cm³, and even more preferably greater than 1.5×10²⁰ atoms/cm³, providing very low resistivities, less than 10 mOhm·cm, at 5 mOhm·cm, or even less than 3 mOhm·cm.

Finally, the intermediate p-SiC disc is subjected to conventional surface preparations by fine rectification and/or by polishing to arrive at the support substrate 20 made of p-SiC having the key characteristics mentioned above, during the description of the composite structure 100.

Considering the preferred crystalline orientation defined, the curvature of the raw disc made of p-SiC remains within a reasonable range to allow the creation of a support substrate 20 with a low curvature, from a raw disc of economically viable thickness. This curvature can be measured by virtue of a confocal white-light sensor, which scans a surface of the disc or substrate, the latter being placed on a support plane of the measuring tool. The difference between the maximum and minimum elevation of the surface scanned by the sensor relative to the support plane is measured. This surface can be interpolated by a median plane, by the least squares method. If this median plane is parallel to the support plane, the deformation measurement is equal to the warp. This method for measuring the strain increases the measurement of the warp in the general case.

By way of example, the curvature (warp) of a raw p-SiC disc of diameter 150 mm and a thickness of less than 1000 μm is targeted less than or equal to 250 μm. It is thus possible after rectification and polishing to obtain a support substrate 20 with a thickness typically less than 500 μm and curvature of less than 100 μm, or even less than 50 μm, or even less than 30 μm.

With reference to the example support substrate 20 shown in FIG. 3B, a p-SiC CVD deposition of thickness 800 μm was carried out on a graphite growth substrate 150 mm in diameter, at a temperature of about 1277° C., with a partial pressure of 16 mbar of MTCS and an NH₃ molar fraction of 4%. The resulting p-SiC disc has a preferred crystallographic orientation with the following texture: C₂₂₀=93%, C₄₂₂=3%, and C₁₁₁+C₂₂₂+C₅₁₁=2%, as shown in FIG. 3A. The nitrogen concentration, measured by SIMS at 1.8×10²⁰ atoms/cm³, provides an electrical resistivity of 10 mOhm·cm (4-point method). The thermal conductivity is evaluated at 240 W/m/K, a high value despite the small grains and the high doping. The curvature of the raw disc is about 210 μm.

A heat treatment at 2000° C. is then applied to the raw disc made of p-SiC, keeping it flat on a flat surface. After which, the steps of thinning by rectification and polishing are carried out in order to sequentially obtain the intermediate disc and the support substrate 20 from FIG. 3B.

The raw disc showed a dominant texture coefficient C₂₂₀, with a significant component (111) close to the interface with the growth substrate. The thickness rich in texture C₁₁₁ was removed by rectification. The heat treatment induced a significant evolution of the microstructure and of the angle of the grains (FIG. 3B): the small grains of (220) orientation tend to coalesce and a mixed orientation (111)+(220)+(200) is obtained. Few small grains of (111) orientation are observed.

In this example, as stated above, the support substrate 20 has a nitrogen concentration of 1.8×10²⁰ atoms/cm³ and an electrical resistivity measured to be 1.2 mOhm·cm. The thermal conductivity is on the order of 270 W/(m/K). Finally, the curvature is measured to be less than 100 μm on a substrate with a diameter of 150 mm and a thickness of between 350 μm and 450 μm.

Empirically, the grains may have an average diameter (measured in a plane perpendicular to the axis z, for example, by EBSD) greater than or equal to 5 μm, in particular, greater than or equal to 10 μm, or even 20 μm or 50 μm in certain support substrates 20 after the aforementioned heat treatment. In particular, the grains of orientation (200) and (400) have an average diameter greater than or equal to 5 μm, in particular, greater than or equal to 10 μm, or even 20 μm or 50 μm, resulting from the heat treatment, which causes the coalescence and recrystallisation of certain grains of (220) orientation.

In the measurement of the average diameter of a grain, it is assumed that different crystals forming one or more macles constitute the same grain and not separate grains.

Thus, the size of the grains tends to increase during the heat treatment, their average diameter being able to be multiplied by at least 2, frequently by 5 or even by 10 or 50, depending on the conditions and the duration of the heat treatment. This is, in particular, the case for the grains of (220) orientation, which prove to have a greater tendency to coalesce and to recrystallize than the grains of (422) orientation, in particular. Thus, the raw discs whose microstructure has a texture coefficient C₄₂₂ less than 40% and a sum of texture coefficients C₂₂₀+C₂₀₀+C₄₀₀ greater than 50% have proven to be particularly sensitive to heat treatments. However, the increase in the grain size during the heat treatment is correlated to an increase in the thermal conductivity, which therefore makes it possible to achieve high thermal conductivity values such as the 270 W/(m·K) already mentioned.

The coalescence of neighboring grains also significantly changes their morphology, since growth by CVD tends to be highly oriented in the direction of the thickness of the raw disc, with grains before heat treatment extending mainly along the axis Z visible in FIG. 3A. As can be seen in FIG. 3B, the heat treatment leads to the appearance of grains of very different morphology.

In particular, the raw disc or support substrate 20 comprises grains having an aspect ratio, defined as being the ratio between, in the numerator, the length of the grain along the Z-axis, and in the denominator, the diameter of the grain in a direction perpendicular to the Z-axis, less than or equal to 10, in particular, less than or equal to 5, in particular, less than or equal to 3. In particular, at least 5% of the grains have such an aspect ratio.

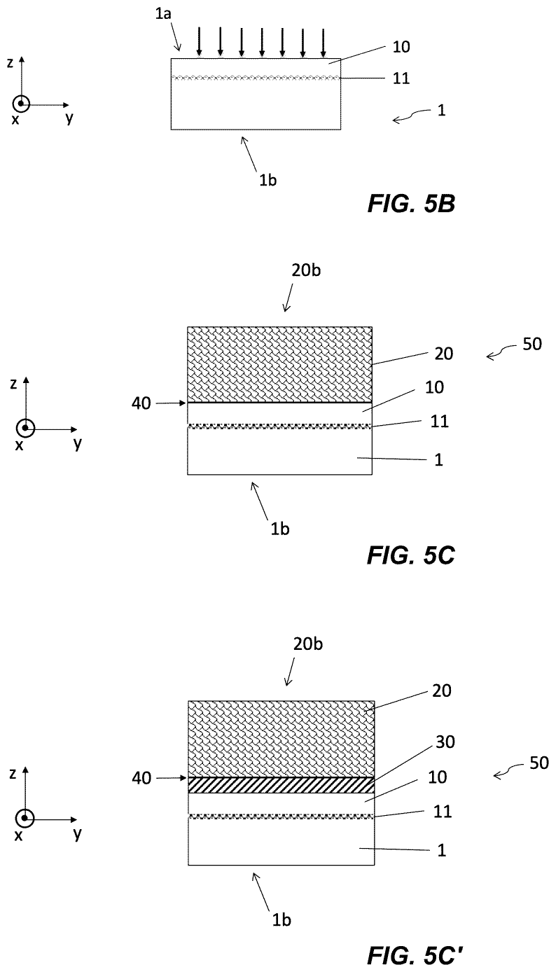

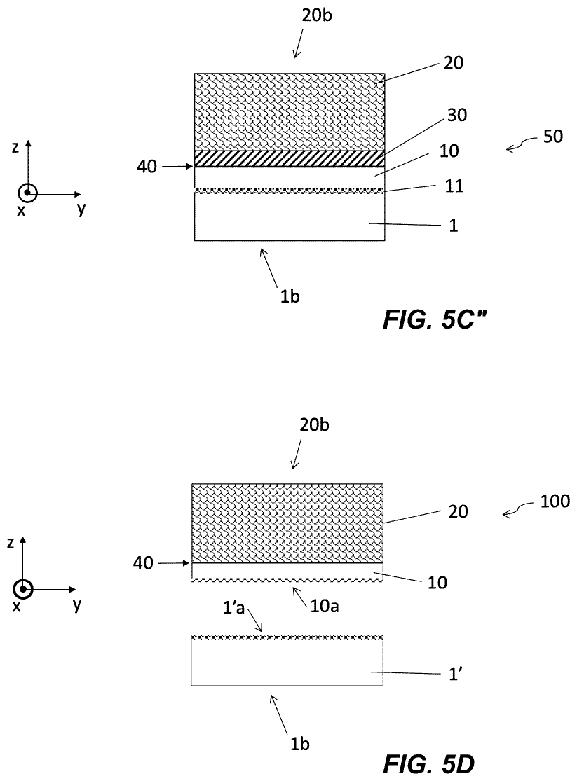

As shown in FIG. 5A, the support substrate 20 has opposite faces 20a, 20b. The face 20a of the support substrate 20 intended to receive the thin film 10 preferably has a roughness of less than or equal to 1 nm RMS (measured by atomic force microscopy on scans of 20 μm x 20 μm), even more preferably less than or equal to 0.5 nm RMS. The face of the support substrate 20 intended to form the rear face of the composite structure 100 may have a greater surface roughness, for example, on the order of 10 nm RMS.

Step a) of the method may optionally include a heat treatment applied to the support substrate 20, at a temperature greater than or equal to 1500° C., typically between 1500° C. and 2000° C., so as to stabilize its polycrystalline structure, and/or to cure defects generated by the rectification or polishing steps, if applicable. Indeed, these temperature ranges are likely to be applied later in the method for manufacturing the composite structure 100.

The manufacturing method according to the present disclosure then comprises a step b) of providing a donor substrate 1 made of a monocrystalline material from which the thin film 10 will be derived (FIG. 5A). As mentioned above with reference to the composite structure 100, the monocrystalline material may be silicon carbide of the 4H, 6H or 3C polytype, diamond, silicon, II-IV or III-V semiconductor compounds (in particular, GaN), etc. The donor substrate 1 is preferably in the form of a plate of 100 mm diameter, 150 mm, 200 mm or even more (identical to or very close to that of the support substrate 20) and with a thickness typically between 300 μm and 800 μm. It has a front face 1a and a rear face 1b. The surface roughness of the front face 1a is advantageously chosen to be less than 1 nm RMS, or even less than 0.5 nm RMS, measured by atomic force microscopy (AFM) on a scan of 20 μm×20 μm. The type of doping and the resistivity of the donor substrate 1 are defined as a function of the requirements of the components that will be produced on and/or in the thin film 10 of the composite structure 100.

Finally, the method comprises a step c) of transferring a thin film 10 from the donor substrate 1 onto the support substrate 20. There are different options, known from the prior art for performing a layer transfer (mechanical, chemical or mechanochemical thinning, separation at a porous layer present in the donor substrate 1, etc.), which will not be described in an exhaustive manner.

According to a preferred embodiment, step c) of the method involves implantation of light species and assembly by direct bonding, according to the principle of the Smart Cut™ method.

A first phase c1) corresponds to the introduction of light species into the donor substrate 1 to form a buried brittle plane 11 delimiting, with a front face la of the donor substrate 1, the thin film 10 to be transferred (FIG. 5B). It should be noted that although the thin film 10 to be transferred has been illustrated as a continuous layer, it could also consist of discontinuous tiles, for example, prepared on the surface of the donor substrate 1.

The light species are preferably hydrogen, helium or a co-implantation of these two species, and are implanted at a determined depth in the donor substrate 1, consistent with the thickness of the targeted thin film 10. These light species will form, around the determined depth, microcavities distributed in a thin film parallel to the free surface 10a of the donor substrate 1, or parallel to the plane (x, y) in the figures. This thin film is called the buried brittle plane 11, for simplicity's sake.

The implantation energy of the light species is chosen so as to reach the determined depth. For example, hydrogen ions will be implanted at an energy of between 10 keV and 250 keV, and at a dose of between 5E16/cm² and 1E17/cm2, to delimit a thin film 10 having a thickness on the order of 100 nm to 1500 nm. It should be noted that a protective layer may be deposited on the front face 1a of the donor substrate 1, prior to the ion implantation step. This protective layer may be composed of a material such as silicon oxide or silicon nitride, for example. It is removed prior to the next phase.

The transfer step c) then comprises a second phase c2) of assembling the donor substrate 1, on the side of its front face 1a, on the support substrate 20, on the side of its first face 20a, by molecular adhesion bonding, along a bonding interface 40 (FIG. 5C).

Optionally, an intermediate layer 30 can be formed on the front face 1a of the donor substrate 1, before or after the introduction of the light species of phase c1), and in any case, before the assembly phase. This intermediate layer 30 may be made of a semiconductor material, for example, silicon or silicon carbide, or made of a metallic material such as tungsten, titanium, etc. The thickness of the intermediate layer 30 is advantageously limited, typically between a few nanometers and a few tens of nanometers.

In the case where the intermediate layer 30 is formed before the first phase c1), the implantation energy (and potentially the dose) of the light species will be adjusted to the passage through this additional layer. In the case where the intermediate layer 30 is formed after phase c1), care will be taken to form this layer by applying a lower thermal budget to the bubbling thermal budget, the bubbling thermal budget corresponding to the appearance of blisters on the surface of the donor substrate 1 due to excessive growth and pressurization of the microcavities in the buried brittle plane 11.

Optionally, an intermediate layer 30 may also be deposited on the face to be assembled of the support substrate 20, prior to the assembly phase; it may be chosen to be of the same nature or of a different nature from the intermediate layer mentioned for the donor substrate 1. An intermediate layer 30 may optionally be deposited on both substrates 1, 20 to be assembled.

The objective of the intermediate layer(s) is essentially to promote the bonding energy (in particular, in the temperature range less than 1100° C.), due to the formation of covalent bonds at lower temperatures than in the case of two directly assembled SiC surfaces, another advantage of this (these) intermediate layer(s) may be to improve the vertical electrical conduction of the bonding interface 40.

The intermediate layer(s) 30 is/are intended to be buried in the bonded assembly 50 after assembly (FIG. 5C′, 5C″), and ultimately, in the composite structure 100. Even if the intermediate layer 30 is continuous during its formation on one and/or the other of the substrates 1, 20, it may, during subsequent heat treatments, become segmented and have a discontinuous nature. It is essentially the case when the initial thickness of the layer is very small, typically less than 10 nm.

Returning to the description of the assembly phase c2), and as is well-known per se, direct bonding by molecular adhesion does not require an adhesive material, since bonds are established on the atomic scale between the assembled surfaces. Several types of molecular adhesion bonding exist, which differ, in particular, by their temperature, pressure, atmosphere conditions or treatments prior to contacting the surfaces. Mention may be made of bonding at room temperature with or without prior plasma activation of the surfaces to be assembled, atomic diffusion bonding (ADB), surface-activated bonding (SAB), etc.

The assembly phase c2) may comprise, prior to the contacting of the faces la, 20a to be assembled, conventional chemical cleaning sequences (for example, RCA cleaning), surface activation (for example, oxygen or nitrogen plasma) or other surface preparations (such as cleaning by scrubbing), capable of promoting the quality of the bonding interface 40 (few defects, strong adhesion energy).

Finally, a third phase c3) comprises the separation along the buried brittle plane 11, which leads to the transfer of the thin film 10 onto the support substrate 20 (FIG. 5D).

The separation along the buried brittle plane 11 usually takes place by applying a heat treatment at a temperature between 800° C. and 1200° C. Such a heat treatment induces the development of the cavities and microcracks in the buried brittle plane 11, and their pressurization by the light species present in gaseous form, until a fracture is propagated along the brittle plane 11. Alternatively or jointly, a mechanical stress can be applied to the bonded assembly and, in particular, at the buried brittle plane 11, so as to propagate or help to mechanically propagate the fracture leading to the separation. At the end of this separation, the composite structure 100 comprising the support substrate 20 and the transferred thin film 10 are obtained, as is the remainder 1′of the donor substrate. The level and type of doping of the thin film 10 are defined by the choice of the properties of the donor substrate 1 or can be adjusted subsequently via known techniques for doping semiconductor layers.

The free surface 10a of the thin film 10 is usually rough after separation: for example, it has a roughness of between 5 nm and 100 nm RMS. Cleaning and/or smoothing phases can be applied to restore a good surface condition (typically a roughness of less than a few angströms RMS). In particular, these phases may comprise a chemical-mechanical smoothing treatment of the free surface of the thin film 10. A removal between 50 nm and 300 nm makes it possible to effectively restore the surface condition of the thin film 10. They may also comprise at least one heat treatment at a temperature of between 1200° C. and 1800° C. Such a heat treatment is applied to evacuate the residual light species of the thin film 10 and to promote the rearrangement of the crystal lattice of the thin film 10. It also makes it possible to reinforce the bonding interface 40. The heat treatment may also comprise or correspond to an epitaxy on the thin film 10, in order to increase the thickness thereof (for example, c-SiC homoepitaxy on a thin film 10 made of c-SiC, GaN heteroepitaxy on a thin film 10 made of c-SiC, or other).

Finally, note that the transfer step c) may comprise a step of reconditioning the remainder 1′ of the donor substrate for reuse as donor substrate 1 for a new composite structure 100. Mechanical and/or chemical treatments, similar to those applied to the composite structure 100, can be implemented at the front face 1′a of the remaining substrate 1′.

The composite structure 100 obtained is extremely robust to heat treatments at very high temperatures that may be applied to improve the quality of the thin film 10 or to manufacture components on and/or in the thin film 10. The support substrate 20 in the composite structure 100 is stable and does not see its curvature significantly increase during high-temperature heat treatments applied to the composite structure 100 for its manufacture and subsequently.

The composite structure 100 according to the present disclosure is particularly suitable for the production of one (or more) high-voltage microelectronic component(s), such as, for example, Schottky diodes, MOSFET transistors, etc. It more generally addresses microelectronic power applications, by allowing excellent vertical electrical conduction, good thermal conductivity and by providing a high-quality monocrystalline thin film 10.

Of course, the present disclosure is not limited to the described embodiments and examples, and variant embodiments can be provided thereto without departing from the scope of the invention as defined by the claims.

1. A composite structure for manufacturing microelectronic components comprising a monocrystalline thin film on a support substrate of polycrystalline silicon carbide, the support substrate having, on each of two opposite faces of the support substrate, a preferential crystalline orientation according to which:
a texture coefficient C₄₂₂ is less than 40%, and
a sum of texture coefficients C₂₂₀+C₂₀₀+C₄₀₀ is greater than 50%.

2. The composite structure of claim 1, wherein the support substrate has an electrical resistivity less than or equal to 10 mOhm·cm.

3. The composite structure of claim 1, wherein the support substrate is nitrogen-doped with a concentration, measured by secondary ion mass spectroscopy, of greater than or equal to 5.0×10¹⁹ atoms/cm³.

4. The composite structure of claim 1, wherein the texture coefficient C₄₂₂ is less than 20%.

5. The composite structure of claim 1, wherein the sum of the texture coefficients C₂₀₀+C₄₀₀ is greater than 1%.

6. The composite structure of claim 1, wherein the monocrystalline thin film is composed of silicon carbide.

7. The composite structure of claim 1, wherein the monocrystalline thin film is composed of gallium nitride.

8. The composite structure of claim 1, wherein the monocrystalline thin film is composed of gallium oxide.

9. The composite structure of claim 1, wherein the monocrystalline thin film is composed of diamond.

10. The composite structure of claim 1, further comprising a continuous or discontinuous intermediate layer between the monocrystalline thin film and the support substrate and composed of at least one metallic or semi-conductive material.

11. The composite structure of claim 10, wherein the intermediate layer is composed of silicon, silicon carbide, tungsten, and/or titanium.

12. The composite structure of claim 1, wherein the support substrate has a thickness of between 50 microns and 650 microns.

13. The composite structure of claim 1, further comprising an electronic component on and/or in the monocrystalline thin film.

14. A method for manufacturing a composite structure comprising a monocrystalline thin film on a support substrate of polycrystalline silicon carbide, the method comprising the following steps:
a) providing a support substrate of polycrystalline silicon carbide having, on each of two opposite faces of the support substrate, a preferential crystalline orientation according to which:
a texture coefficient C₄₂₂ is less than 40%, and
the sum of texture coefficients C₂₂₀+C₂₀₀+C₄₀₀ is greater than 50%.
b) providing a donor substrate of a monocrystalline material; and
c) transferring a thin film from the donor substrate to the support substrate.

15. The method of claim 14, wherein the step c) comprises the following steps:
c1) forming a buried brittle plane in the donor substrate delimiting the thin film between the buried brittle plane and a front face of the donor substrate
c2) assembling, by molecular adhesion bonding, the donor substrate and the support substrate, directly or via an intermediate layer; and
c3) separating along the buried brittle plane to transfer the thin film to the support substrate.

16. The method of claim 15, wherein step c2) comprises, before the assembling of the donor substrate and the support substrate:
forming an intermediate layer on the donor substrate, before or after step c1), and/or
forming an intermediate layer on the support substrate, the intermediate layer being formed of at least one metallic or semi-conductive material, chosen from among the group consisting of silicon, silicon carbide, tungsten and titanium.

17. The method of claim 14, further comprising forming electronic components on and/or in the thin film of the composite structure.

18. The method of claim 17, wherein the forming of the electronic components comprises performing homoepitaxy or heteroepitaxy on the thin film.

19. The composite structure of claim 1, wherein the sum of texture coefficients C₂₂₀+C₂₀₀+C₄₀₀ is greater than 80%.

20. The method of claim 14, wherein the sum of texture coefficients C₂₂₀+C₂₀₀+C₄₀₀ is greater than 80%.
